(19) United States
(12) Patent Application Publication
(10) Pub. No.: US 2010/0200062 A1
(43) Pub. Date: Aug. 12, 2010

(54) SOLAR CELL AND METHOD FOR MANUFACTURING THE SAME

(75) Inventors: Jin Hong, Gyeonggi-do (KR); Joung Sik Kim, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/677,801

(22) PCT Filed: Sep. 16, 2008
(86) PCT No.: PCT/KR2008/005462

§ 371 Date: Mar. 11, 2010

(30) Foreign Application Priority Data
Sep. 17, 2007 (KR) 10-2007-0093998

(51) Int. Cl. H01L 31/0368; H01L 31/0376; H01L 31/18; H01L 31/20

(52) U.S. Cl. 136/258; 438/97; 438/96; 257/E31.044; 257/E31.048

(57) ABSTRACT

A solar cell and a method for manufacturing the same is disclosed, wherein the solar cell comprises a first cell comprised of a semiconductor wafer with a PN structure; a second cell comprised of a thin film semiconductor layer with a PIN structure, formed on one surface of the first cell; a first electrode layer formed on one surface of the second cell; and a second electrode layer formed on the other surface of the first cell. Unlike the related art solar cell, the solar cell according to the present invention can absorb the light of long-wavelength range in the first cell, and the light of short-wavelength range in the second cell. As a result, it is possible for the solar cell according to the present invention to absorb the light of all ranges, thereby realizing the high efficiency of 20% or above. Also, the entire process time becomes shortened since there is no requirement for the procedure of forming the silicon thin film for a long period of time.

### TECHNICAL FIELD

The present invention relates to a solar cell, and more particularly, to a solar cell made with a combination of a wafer type solar cell and a thin film type solar cell.

### BACKGROUND ART

A solar cell with a property of semiconductor converts a light energy into an electric energy. A structure and principle of the solar cell according to the related art will be briefly explained as follows. The solar cell is formed in a PN-junction structure where a P(positive)-type semiconductor makes a junction with an N(negative)-type semiconductor. When a solar ray is incident on the solar cell of the PN-junction structure, holes(+) and electrons(−) are generated in the semiconductor owing to the energy of solar ray. By an electric field generated in a PN-junction area, the holes(+) are drifted toward the P-type semiconductor, and the electrons(−) are drifted toward the N-type semiconductor, whereby an electric power is produced with an occurrence of electric potential.

The solar cell is largely classified into a wafer type solar cell and a thin film type solar cell.

The wafer type solar cell uses a substrate made of a semiconductor material such as silicon. In more detail, the wafer type solar cell may be manufactured by monocrystalline silicon with PN structure, or poly-crystalline silicon with PN structure. The wafer type solar cell using the monocrystalline silicon with PN structure can realize high efficiency since the monocrystalline silicon has a high degree of purity and a low crystal-defect density. However, the high-priced monocrystalline silicon is inappropriate for the mass production. In the meantime, the wafer type solar cell using the poly-crystalline silicon with PN structure is appropriate for the mass production owing to the low-priced poly-crystalline silicon and inexpensive process cost. However, it is difficult for the wafer type solar cell using the poly-crystalline silicon with PN structure to realize the high efficiency. Also, the wafer type solar cell using the poly-crystalline silicon with PN structure absorbs a light in a long-wavelength range, but it is difficult for the wafer type solar cell using the poly-crystalline silicon to absorb a light in a short-wavelength range. Accordingly, the maximum value of efficiency in the wafer type solar cell using the poly-crystalline silicon is about 19%, so that the high-efficiency solar cell can not be realized.

The thin film type solar cell is manufactured by forming a semiconductor in type of a thin film on a substrate made of glass. Since the thin film type solar cell in a thin profile can be manufactured of a low-priced material, it is appropriate for the mass production. The thin film type solar cell includes a thin film type silicon layer of a PIN structure with a P(positive)-type silicon layer, an I(intrinsic)-type silicon layer, and an N(negative)-type silicon layer deposited in sequence. However, a low light-absorbing coefficient and a thin profile in the thin film type silicon layer may cause limitation on light-absorbing efficiency.

Accordingly, a thin film type solar cell with a double-layered PIN structure instead of a single-layered PIN structure has been proposed. However, the thin film type solar cell with the double-layered PIN structure has a problem of long process time. In addition, even though the thin film type solar cell is manufactured by the double-layered PIN structure, the efficiency is about 15% or less.

The wafer type solar cell using the poly-crystalline silicon with PN structure and the thin film type solar cell with the double-layered PIN structure have been developed in that they are appropriate for the mass production. However, in case of the wafer type solar cell using the poly-crystalline silicon with PN structure, the high efficiency can not be realized since the light of all ranges is not absorbed uniformly. Also, in case of the thin film type solar cell with the double-layered PIN structure, it is difficult to realize the high efficiency and to raise the productivity due to the long process time.

### DISCLOSURE OF INVENTION

### Technical Problem

Therefore, the present invention has been made in view of the above problems, and it is an object of the present invention to provide a solar cell and a method for manufacturing the same, which can obtain high efficiency with a decreased process time.

### Technical Solution

To achieve these objects and other advantages and in accordance with the purpose of the invention, as embodied and broadly described herein, a solar cell comprises a first cell comprised of a semiconductor wafer with a PN structure; a second cell comprised of a thin film semiconductor layer with a PIN structure, formed on one surface of the first cell; a first electrode layer formed on one surface of the second cell; and a second electrode layer formed on the other surface of the first cell.

The solar cell further includes a transparent conductive layer having an uneven surface, positioned between the second cell and the first electrode layer.

The first cell is comprised of a P-type polycrystalline silicon layer, and an N-type polycrystalline silicon layer on one surface of the P-type polycrystalline silicon layer. At this time, a P⁺-type polycrystalline silicon layer is additionally formed on the other surface of the P-type polycrystalline silicon layer, and the second cell is comprised of a P-type amorphous silicon layer, an I-type amorphous silicon layer, and an N-type amorphous silicon layer in sequence.

The first cell is comprised of an N-type polycrystalline silicon layer, and a P-type polycrystalline silicon layer on one surface of the N-type polycrystalline silicon layer. At this time, an N⁺-type polycrystalline silicon layer is additionally formed on the other surface of the N-type polycrystalline silicon layer, and the second cell is comprised of an N-type amorphous silicon layer, an I-type amorphous silicon layer, and a P-type amorphous silicon layer in sequence.

In another aspect of the present invention, a method for manufacturing a solar cell comprises forming a first cell comprised of a semiconductor wafer with a PN structure; forming a second cell comprised of a thin film semiconductor layer with an PIN structure on one surface of the first cell; and forming a first electrode layer on one surface of the second cell, and a second electrode layer on the other surface of the first cell.

At this time, the method further includes forming a transparent conductive layer having an uneven surface between the second cell and the first electrode layer. Also, forming the first cell comprises preparing a P-type polycrystalline silicon wafer; and forming an N-type polycrystalline silicon layer on one surface of the P-type polycrystalline silicon wafer by doping the P-type polycrystalline silicon wafer with an N-type dopant. Also, preparing the P-type polycrystalline silicon wafer comprises forming one uneven surface in the P-type polycrystalline silicon wafer so as to make one uneven surface in the N-type polycrystalline silicon layer. In addition, the method further includes forming a P⁺-type polycrystalline silicon layer on the other surface of the P-type polycrystalline silicon wafer. Also, forming the second cell comprises depositing a P-type amorphous silicon layer, an I-type amorphous silicon layer, and an N-type amorphous silicon layer in sequence.

At this time, forming the first cell comprises forming an N-type polycrystalline silicon wafer; and forming a P-type polycrystalline silicon layer on one surface of the N-type polycrystalline silicon wafer by doping the N-type polycrystalline silicon wafer with a P-type dopant. In this case, preparing the N-type polycrystalline silicon wafer comprises forming one uneven surface in the N-type polycrystalline silicon wafer so as to make one uneven surface in the P-type polycrystalline silicon layer. Furthermore, the method includes forming an N⁺-type polycrystalline silicon layer on the other surface of the N-type polycrystalline silicon wafer. Also, forming the second cell comprises depositing an N-type amorphous silicon layer, an I-type amorphous silicon layer, and a P-type amorphous silicon layer in sequence.

In another aspect of the present invention, a solar cell comprises a first cell comprised of a semiconductor wafer; a second cell comprised of a thin film semiconductor layer, formed on one surface of the first cell; a first electrode layer formed on one surface of the second cell; and a second electrode layer formed on the other surface of the first cell, wherein a light-wavelength range absorbed in the first cell is different from a light-wavelength range absorbed in the second cell.

At this time, the first cell is comprised of a polycrystalline silicon layer with PN a structure, and the second cell is comprised of an amorphous silicon layer with a PIN structure.

It is to be understood that both the foregoing general description and the following detailed description of the present invention are exemplary and explanatory and are intended to provide further explanation of the invention as claimed.

### Advantageous Effects

The solar cell according to the present invention and the method for manufacturing the same has the following advantages.

First, the solar cell according to the present invention is comprised of the semiconductor wafer with PN structure for the first cell, and the thin film semiconductor layer with PIN structure for the second cell. Thus, unlike the related art solar cell, the solar cell according to the present invention can absorb the light of long-wavelength range in the first cell, and the light of short-wavelength range in the second cell. As a result, it is possible for the solar cell according to the present invention to absorb the light of all ranges, thereby realizing the high efficiency of 20% or above.

Also, the solar cell according to the present invention uses the semiconductor wafer with PN structure as the first cell. Thus, the entire process time becomes shortened since there is no requirement for the procedure of forming the silicon thin film for a long period of time.

In addition, the solar cell according to the present invention is formed by the thin film semiconductor layer of amorphous silicon with PIN structure and the semiconductor wafer of polycrystalline silicon with PN structure, so that it is possible to prevent the amorphous silicon from being deteriorated when the amorphous silicon is exposed to the light for a long period of time.

When forming the thin film semiconductor layer with PIN structure according to the present invention, the P-type amorphous silicon layer is formed adjacent to the solar ray incidence face, whereby it enables the improved efficiency in collection of carrier by incident ray.

Furthermore, the transparent conductive layer and the N-type polycrystalline silicon layer may have the uneven surfaces, or the transparent conductive layer and the P-type polycrystalline silicon layer may have the uneven surfaces, thereby improving the light-absorbing efficiency.

According as the P⁺-type polycrystalline silicon layer or N⁺-type polycrystalline silicon layer is formed, it is possible to prevent the electrons generated by the solar ray from being recombined in the rear surface of the semiconductor wafer, thereby improving the solar cell efficiency.

As the semiconductor wafer with PN structure is formed by the plasma ion-doping method, it is possible to realize high preciseness and realization, to enable the decrease of process time, and to improve the productivity without performing the additional procedure of removing the byproducts.

### BRIEF DESCRIPTION OF THE DRAWINGS

FIG. 1 is a cross section view illustrating a solar cell according to one embodiment of the present invention;

FIG. 2 is a cross section view illustrating a solar cell according to another embodiment of the present invention;

FIGS. 3A to 3H are cross section views illustrating a method for manufacturing a solar cell according to one embodiment of the present invention; and

FIGS. 4A to 4G are cross section views illustrating a method for manufacturing a solar cell according to another embodiment of the present invention.

### BEST MODE FOR CARRYING OUT THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a solar cell according to the present invention and a method for manufacturing the same will be explained with reference to the accompanying drawings.

<Solar Cell>

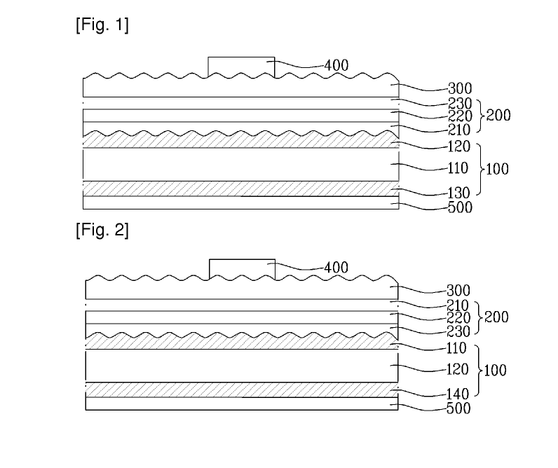

FIG. 1 is a cross section view illustrating a solar cell according to one embodiment of the present invention. As shown in FIG. 1, the solar cell according to one embodiment of the present invention includes a semiconductor wafer 100, a thin film semiconductor layer 200, a transparent conductive layer 300, a first electrode layer 400, and a second electrode layer 500.

The semiconductor wafer 100 forms a first cell of the solar cell, wherein the semiconductor wafer 100 is formed in a PN structure. The semiconductor wafer 100 with PN structure includes a P-type polycrystalline silicon layer 110, an N-type polycrystalline silicon layer 120 on an upper surface of the P-type polycrystalline silicon layer 110, and a P⁺-type polycrystalline silicon layer 130 on a lower surface of the P-type polycrystalline silicon layer 110.

The semiconductor wafer 100 with PN structure may be formed through sequential steps of forming an N-type polycrystalline silicon layer by doping an upper surface of P-type polycrystalline wafer with an N-type dopant using a high-temperature diffusion or plasma ion-doping method; and forming a highly-doped P⁺-type polycrystalline silicon layer by doping a lower surface of P-type polycrystalline wafer with P-type dopant. Preferably, the N-type polycrystalline silicon layer 120 has an uneven surface. This is because the uneven surface of N-type polycrystalline silicon layer 120 is advantageous to the increase of light-absorbing area, whereby the solar cell efficiency can be improved.

The P⁺-type polycrystalline silicon layer 130 is optional for the solar cell, however, it is preferable that the P⁺-type polycrystalline silicon layer 130 be formed on the lower surface of P-type polycrystalline silicon layer 110. If forming the P⁺-type polycrystalline silicon layer 130, it is possible to prevent electrons generated by solar ray from being recombined in the rear surface of first cell, thereby improving the solar cell efficiency.

The thin film semiconductor layer 200 forms a second cell of the solar cell, wherein the thin film semiconductor layer 200 is formed in a PIN structure. The thin film semiconductor layer 200 with PIN structure is formed by sequentially depositing a P-type amorphous silicon layer 210, an I-type amorphous silicon layer 220, and an N-type amorphous silicon layer 230. The thin film semiconductor layer 200 with PIN structure may be formed by a plasma CVD method. In the thin film semiconductor layer 200 with PIN structure, a depletion is generated in the I-type amorphous silicon layer 220 by the P-type amorphous silicon layer 210 and the N-type amorphous silicon layer 230, so that an electric field occurs. Thus, the electrons and holes generated by the solar ray are drifted by the electric field, and the drifted holes and electrons are collected in the P-type amorphous silicon layer 210 and N-type amorphous silicon layer 230. At this time, the P-type amorphous silicon layer 210 is formed at a thickness between 50 Å and 500 Å. Also, the P-type amorphous silicon layer 210 may be formed of P-type amorphous silicon carbide (SiC).

It is preferable that a light-wavelength range absorbed in the semiconductor wafer 100 for the first cell be different from a light-wavelength range absorbed in the thin film semiconductor layer 200 for the second cell, so that the thin film type solar cell can absorb the light of wide ranges. Accordingly, the semiconductor wafer 100 for the first cell is formed of the polycrystalline silicon layer with PN structure so as to absorb long-wavelength light, and the thin film type semiconductor layer 200 for the second cell is formed of the amorphous silicon layer with PIN structure so as to absorb short-wavelength light. The first cell comprised of the polycrystalline silicon layer absorbs the light of long-wavelength range corresponding to 500 nm to 1100 nm, and the second cell comprised of the amorphous silicon layer absorbs the light of short-wavelength range corresponding to 300 nm to 800 nm.

The transparent conductive layer 300 is positioned between the first electrode layer 400 and the N-type amorphous silicon layer 230 of the thin film semiconductor layer 200 with PIN structure. In this case, the transparent conductive layer 300 may be formed of a transparent conductive material, for example, ZnO, ZnO:B, ZnO:Al, SnO₂, SnO₂:F, or ITO (Indium Tin Oxide) by sputtering or MOCVD (Metal Organic Chemical Vapor Deposition).

The transparent conductive layer 300 corresponds to a solar-ray incidence face. That is, it is important for the transparent conductive layer 300 to transmit the solar ray into the inside of solar cell with the minimized loss. For this, a texturing process may be additionally performed to the transparent conductive layer 300. Through the texturing process, a surface of material layer is provided with an uneven surface, that is, a texture structure, by an etching process using photolithography, an anisotropic etching process using a chemical solution, or a mechanical scribing process. According as the texturing process is performed to the transparent conductive layer 300, a solar-ray reflection ratio on the solar cell is decreased and a solar-ray absorbing ratio on the solar cell is increased owing to a dispersion of the solar ray, thereby improving the solar cell efficiency.

The first electrode layer 400 may be formed of metal such as Ag, Al, Ag⁺Mo, Ag⁺Ni, Ag⁺Cu, Ag⁺Al, Ag⁺Mg, Ag⁺Mn, Ag⁺Sb, Ag⁺Zn, or Ag⁺Al⁺Zn by sputtering or printing. Since the first electrode layer 400 is formed on the solar-ray incidence face, preferably, the first electrode layer 400 is patterned to occupy a small area so as to increase the incidence of solar ray. Accordingly, the first electrode layer 400 may be made through sequential steps of forming an electrode layer by sputtering, and patterning the electrode layer by etching. In another way, the first electrode layer 400 may be made by directly forming a predetermined pattern through the use of a screen printing method, an inkjet printing method, a gravure printing method, or a micro-contact printing method.

In the case of the screen printing method, a material is transferred to a predetermined body through the use of a squeeze. The inkjet printing method sprays a material onto a predetermined body through the use of inkjet, to thereby form a predetermined pattern thereon. In the case of the gravure printing method, a material is coated on an intaglio plate, and then the coated material is transferred to a predetermined body, thereby forming a predetermined pattern on the predetermined body. The micro-contact printing method forms a predetermined pattern of material on a predetermined body through the use of predetermined mold.

Like the first electrode layer 400, the second electrode layer 500 is formed of metal such as Ag, Al, Ag⁺Mo, Ag⁺Ni, Ag⁺Cu, Ag⁺Al, Ag⁺Mg, Ag⁺Mn, Ag⁺Sb, Ag⁺Zn, or Ag³⁰ Al⁺Zn by sputtering or printing. Since the second electrode layer 500 is not provided on the solar-ray incidence face, the second electrode layer 500 is formed on the entire lower surface of the semiconductor wafer 100 with PN structure. If needed, it is possible to pattern the second electrode layer 500 at the same size as the first electrode layer 400.

The first cell comprised of the semiconductor wafer 100 with PN structure absorbs the long-wavelength light, and the second cell comprised of the thin film semiconductor layer 200 with PIN structure absorbs the short-wavelength light. As a result, the solar cell according to the present invention can absorb the solar ray of all ranges, whereby it is possible to realize the high efficiency above 20%. Also, since the first cell for absorbing the long-wavelength light is formed of the semiconductor wafer 100 with PN structure, it is unnecessary to perform a procedure taking long time, required in the related art, for depositing a silicon thin film so as to absorb the long-wavelength light.

Also, an amorphous semiconductor material is disadvantageous in that it is rapidly deteriorated when it is exposed to the solar ray for a long period of time. The solar cell according to the present invention is comprised of the first cell with the light-absorbing layer of polycrystalline silicon and the second cell with the light-absorbing layer of amorphous silicon. In comparison to the related art solar cell with the light-absorbing layer of only amorphous silicon which is identical in thickness to the total of the light-absorbing layers in the first and second cells according to the present invention, the solar cell with the first and second cells according to the present invention can prevent the deterioration of solar cell efficiency.

In the solar cell according to one embodiment of the present invention, the semiconductor wafer 100 with PN structure is comprised of the N-type polycrystalline silicon layer 120 on the upper surface of P-type polycrystalline silicon layer 110; and the thin film semiconductor layer 200 with PIN structure is comprised of the I-type amorphous silicon layer 220 on the upper surface of P-type amorphous silicon layer 210, and the N-type amorphous silicon layer 230 on the upper surface of I-type amorphous silicon layer 220. That is, both in the semiconductor wafer 100 and the thin film semiconductor layer 200, the P-type semiconductor layer is positioned at the lower part, and the N-type semiconductor layer is positioned at the upper part.

In a case of solar cell according to another embodiment of the present invention, the P-type semiconductor layer is positioned at the upper part, and the N-type semiconductor layer is positioned at the lower part.

FIG. 2 is a cross section view illustrating a solar cell according to another embodiment of the present invention. Except a semiconductor wafer 100 with PN and a thin film semiconductor layer 200 with PIN structure, the solar cell according to another embodiment of the present invention shown in FIG. 2 is identical in structure to the solar cell according to one embodiment of the present invention shown in FIG. 1, whereby a detailed explanation for the same parts will be omitted. That is, a transparent conductive layer 300, a first electrode layer 400, and a second electrode layer 500 in the solar cell according to another embodiment of the present invention are the same as those in the solar cell according to one embodiment of the present invention, so that a detailed explanation for the transparent conductive layer 300, the first electrode layer 400, and the second electrode layer 500 will be omitted.

As shown in FIG. 2, the semiconductor wafer 100 with PN structure is comprised of an N-type polycrystalline silicon layer 120, a P-type polycrystalline silicon layer 110 on an upper surface of the N-type polycrystalline silicon layer 120, and an N⁺-type polycrystalline silicon layer 140 on a lower surface of the N-type polycrystalline silicon layer 120.

The semiconductor wafer 100 with PN structure is obtained through sequential steps of forming the P-type polycrystalline silicon layer by doping an upper surface of N-type polycrystalline silicon wafer with P-type dopant using a high-temperature diffusion or plasma ion-doping method, and forming the highly-doped N⁺-type polycrystalline silicon layer by doping a lower surface of N-type polycrystalline silicon wafer with N-type dopant. Preferably, the P-type polycrystalline silicon layer 110 has an uneven surface which is advantageous to the increase of light-absorbing area.

The thin film semiconductor layer 200 with PIN structure is comprised of an N-type amorphous silicon layer 230, an I-type amorphous silicon layer 220, and a P-type amorphous silicon layer 210 deposited in sequence. The thin film semiconductor layer 200 with PIN structure may be formed by a plasma CVD method.

The solar cells, shown in FIGS. 1 and 2, according to the embodiments of the present invention are explained above, and each solar cell has the following advantages.

First, the solar cell shown in FIG. 1 has the advantage of easy procedure for forming the semiconductor wafer 100 with PN structure. In order to form the semiconductor wafer 100 with PN structure, it is necessary to perform the procedure of 1) forming the N-type polycrystalline silicon layer by doping the upper surface of P-type polycrystalline silicon wafer with the N-type dopant through the high-temperature diffusion or plasma ion-doping method (for the solar cell shown in FIG. 1), or 2) forming the P-type polycrystalline silicon layer by doping the upper surface of N-type polycrystalline silicon wafer with the P-type dopant through the high-temperature diffusion or plasma ion-doping method (for the solar cell shown in FIG. 2).

When performing the doping procedure using the high-temperature diffusion method, doping of the N-type dopant on the upper surface of P-type polycrystalline silicon wafer (case of forming the solar cell shown in FIG. 1) can be performed at a lower temperature in comparison to doping of the P-type dopant on the upper surface of N-type polycrystalline silicon wafer (case of forming the solar cell shown in FIG. 2), whereby it becomes easier.

Next, in case of the solar cell shown in FIG. 2, the P-type amorphous silicon layer 210 of the thin film semiconductor layer 200 with PIN structure is positioned adjacent to the solar ray incidence face, whereby it enables the improved efficiency in collection of carrier by incident ray. This is because a drift mobility of the hole is less than a drift mobility of the electron. In order to maximize the collection efficiency by the incident ray, the P-type amorphous silicon layer 210 is positioned adjacent to the solar ray incidence face.

<Method for Manufacturing Solar Cell>

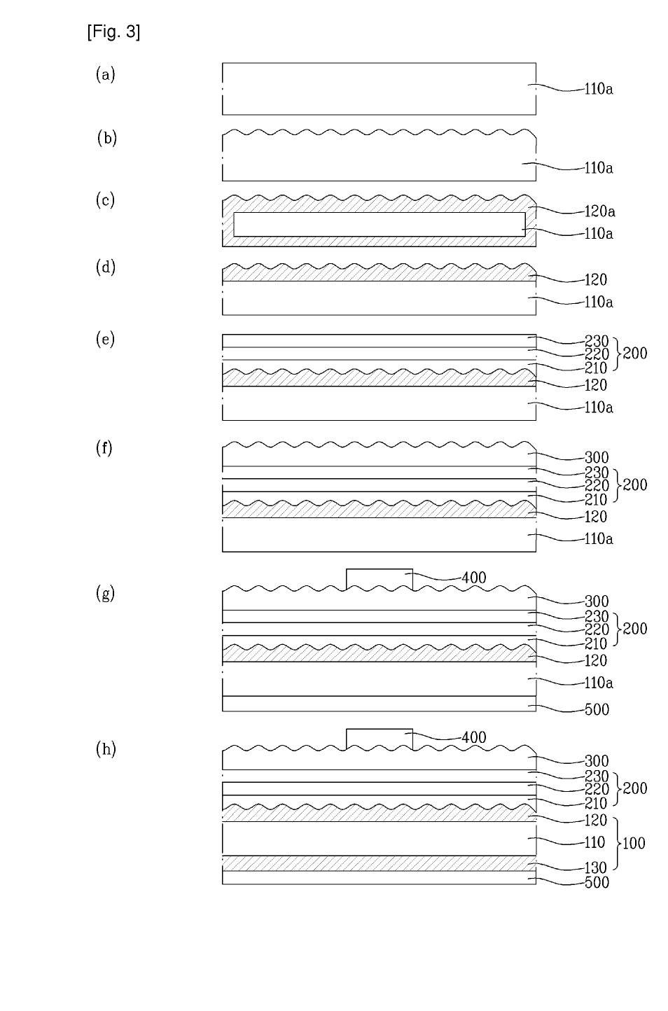

FIGS. 3A to 3H are cross section views illustrating a method for manufacturing a solar cell according to one embodiment of the present invention, which are related with a method for manufacturing the solar cell of FIG. 1 by forming a semiconductor wafer with PN structure through the use of high-temperature diffusion method.

First, as shown in FIG. 3A, a P-type polycrystalline wafer 110a is prepared. Then, as shown in FIG. 3B, the upper surface of P-type polycrystalline wafer 110a becomes uneven by patterning. The uneven upper surface of P-type polycrystalline wafer 110a is provided to obtain the uneven surface of N-type polycrystalline silicon layer.

Generally, a monocrystalline silicon wafer may have an uneven surface by alkali-etching. However, in case of a polycrystalline silicon wafer, it is difficult to form an uneven surface in the polycrystalline silicon wafer by alkali-etching because many crystal grains are oriented at different directions. In order to obtain the uneven surface of polycrystalline silicon wafer, it is preferable to perform reactive ion etching (RIE), isotropic etching using acid solution, or mechanical etching.

The RIE enables the uniform formation of uneven surface in the wafer without regard to the crystal orientation of crystal grains. Thus, the RIE can be applied to the procedure for forming the uneven surface of polycrystalline silicon wafer. Especially, if applying the RIE, the procedures of FIGS. 3B and 3C may be performed in the same chamber. The RIE uses a main gas as Cl₂, SF₆, NF₃, HBr, or mixture thereof, and an additional gas as Ar, O₂, N₂, He, or mixture thereof.

As shown in FIG. 3C, the surface of P-type polycrystalline silicon wafer 110a is doped with N-type polycrystalline silicon 120a by diffusing N-type dopant on the P-type polycrystalline silicon wafer 110a. During this procedure, the N-type dopant is diffused at a high temperature. In more detail, while the P-type polycrystalline silicon wafer 110a is placed in a furnace at a high temperature above 800° C., the N-type dopant gas such as POCl₃ or PH₃ is supplied so that the N-type dopant is diffused on the surface of P-type polycrystalline silicon wafer 110a.

Since the high-temperature diffusion procedure is performed at a high temperature above 800° C., byproducts such as phosphor-silicate glass (PSG) may be generated in the surface of P-type polycrystalline silicon wafer 110a. The PSG causes a current cut-off problem in the solar cell. In order to improve the solar cell efficiency, it is preferable to remove the PSG through the use of etchant.

As shown in FIG. 3D, the N-type polycrystalline silicon layer 120a is removed from the lateral and lower sides of P-type polycrystalline silicon wafer 110a, so that the N-type polycrystalline silicon layer 120 remains only on the upper surface of P-type polycrystalline silicon wafer 110a. If the high-temperature diffusion procedure is performed, the N-type polycrystalline silicon layer 120a is formed on the entire surface of P-type polycrystalline silicon wafer 110a, as shown in FIG. 3C. This structure may cause a problem of leakage current. In this respect, the N-type polycrystalline silicon layer 120a is removed from the lateral and lower surfaces of P-type polycrystalline silicon wafer 110a so as to prevent the leakage current. For removing the N-type polycrystalline silicon layer 120, wet-etching or dry-etching may be used.

As shown in FIG. 3E, the thin film semiconductor layer 220 with PIN structure is formed on the upper surface of N-type polycrystalline silicon layer 120. The thin film semiconductor layer 200 with PIN structure is formed by sequentially depositing the P-type amorphous silicon layer 210, the I-type amorphous silicon layer 220, and the N-type amorphous silicon layer 230 through the plasma CVD method. The P-type amorphous silicon layer 210 is formed at a thickness between 50 Å and 500 Å. Also, the P-type amorphous silicon layer 210 may be formed of P-type amorphous silicon carbide (SiC).

Next, as shown in FIG. 3F, the transparent conductive layer 300 is formed on the upper surface of N-type amorphous silicon layer 230. The transparent conductive layer 300 may be formed of the transparent conductive material, for example, ZnO, ZnO:B, ZnO:Al, ZnO:H, SnO₂, SnO₂:F, or ITO (Indium Tin Oxide) by sputtering or MOCVD (Metal Organic Chemical Vapor Deposition). Preferably, the surface of transparent conductive layer 300 becomes uneven by the texturing procedure.

Referring to FIG. 3G, the first electrode layer 400 is formed on the upper surface of transparent conductive layer 300, and the second electrode layer 500 is formed on the lower surface of P-type polycrystalline silicon wafer 110a. In this case, the second electrode layer 500 may be formed after firstly forming the first electrode layer 400, or the first electrode layer 400 may be formed after firstly forming the second electrode layer 500. The first and second electrode layers 400 and 500 may be formed of metal such as Ag, Al, Ag⁺Mo, Ag⁺Ni, Ag⁺Cu, Ag⁺Al, Ag⁺Mg, Ag⁺Mn, Ag⁺Sb, Ag⁺Zn, or Ag⁺ Al⁺Zn by sputtering or printing. Also, the area size of first electrode layer 400 is decreased by patterning, preferably.

Next, as shown in FIG. 3H, the lower side of P-type polycrystalline silicon wafer 110a is doped with the P-type dopant, whereby the P⁺-type polycrystalline silicon layer 130 is formed on the lower surface of P-type polycrystalline silicon layer 110. At this time, if the second electrode layer 500 is formed of aluminum Al corresponding to trivalent metal, the lower side of P-type polycrystalline silicon wafer 110a is doped with aluminum Al by applying a heat treatment to the second electrode layer 500.

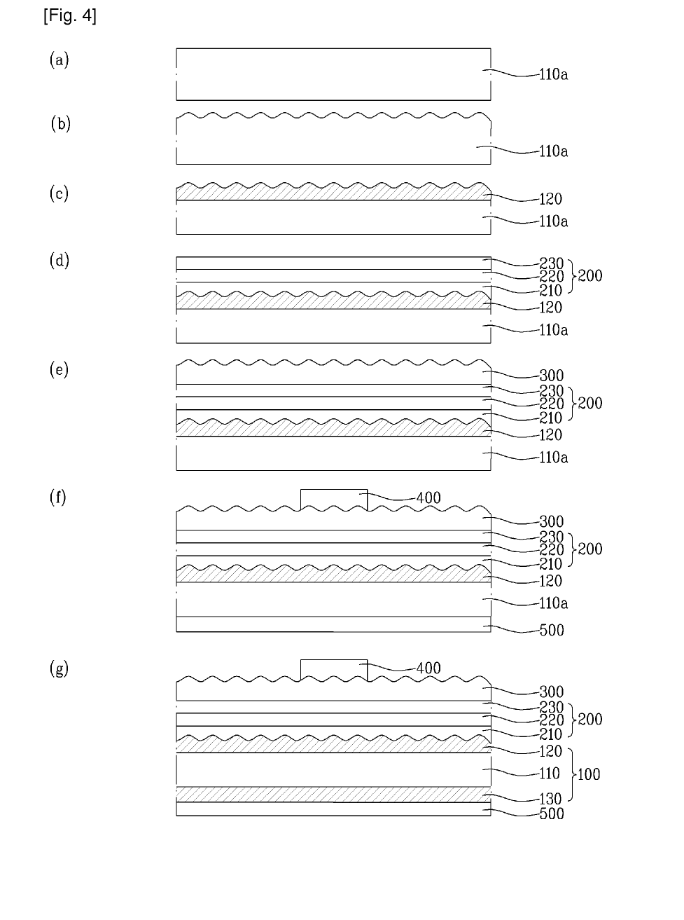

If the second electrode layer 500 is not formed of the trivalent metal, the P⁺-type polycrystalline silicon layer 130 is formed in the lower surface of the P-type polycrystalline silicon wafer 110a by doping the lower side of P-type polycrystalline silicon wafer 110a with trivalent ions. This procedure may be performed by a plasma ion-doping method (See a plasma ion-doping method of FIGS. 4A to 4G) using a dopant gas such as B₂H₆. If forming the P⁺-type polycrystalline silicon layer 130 by the plasma ion-doping method, this procedure is performed before the procedure of forming the second electrode layer 500, preferably. In more detail, this procedure is performed immediately after the procedure of FIG. 3D, the procedure of FIG. 3E, or the procedure of FIG. 3F.

The aforementioned explanation is related with the method of manufacturing the solar cell of FIG. 1. However, the aforementioned explanation also includes the method for manufacturing the solar cell of FIG. 2.

Hereinafter, the method for manufacturing the solar cell of FIG. 2 by forming the semiconductor wafer with PN structure through the use of high-temperature diffusion will be explained in brief.

First, the N-type polycrystalline silicon wafer is prepared. Then, the upper surface of N-type polycrystalline silicon wafer becomes uneven. After that, the N-type polycrystalline silicon wafer is doped with the P-type dopant so that the surface of N-type polycrystalline silicon wafer is doped with the P-type polycrystalline silicon.

In more detail, while the N-type polycrystalline silicon wafer is placed in a furnace at a high temperature above 850° C., the P-type dopant gas such as B₂H₆ including boron (B) is supplied thereto so that the P-type dopant is diffused on the surface of N-type polycrystalline silicon wafer. This high-temperature diffusion procedure is performed at a high temperature above 850° C., whereby byproducts such as boro-silicate glass (BSG) may be generated in the surface of N-type polycrystalline silicon wafer. However, the BSG causes a cut-off problem of current in the solar cell. In order to improve the solar cell efficiency, it is preferable to remove the BSG through the use of etchant.

According as the P-type polycrystalline silicon layer is removed from the lateral and lower surfaces of N-type polycrystalline silicon wafer, the P-type polycrystalline silicon layer remains only on the upper surface of N-type polycrystalline silicon wafer. Then, the thin film semiconductor layer with PIN structure is formed on the upper surface of P-type polycrystalline silicon layer. The thin film semiconductor layer with PIN structure is formed by sequentially depositing the N-type amorphous silicon layer, the I-type amorphous silicon layer, and the P-type amorphous silicon layer through the plasma CVD method. Thereafter, the transparent conductive layer is formed on the upper surface of P-type amorphous silicon layer. Then, the first electrode layer is formed on the upper surface of transparent conductive layer, and the second electrode layer is formed on the lower surface of N-type polycrystalline silicon wafer.

In the meantime, the N⁺-type polycrystalline silicon layer may be formed on the lower surface of N-type polycrystalline silicon wafer. In this case, the N⁺-type polycrystalline silicon layer may be formed by performing the plasma ion-doping method using the N-type dopant gas such as POCl₃ or PH₃. Preferably, this procedure is performed before forming the second electrode layer.

FIGS. 4A to 4G are cross section views illustrating a method for manufacturing a solar cell according to another embodiment of the present invention, which are related with a method for manufacturing the solar cell of FIG. 1 by forming a semiconductor wafer with PN structure through the use of plasma ion-doping method.

Hereinafter, the detailed explanation about the same parts as those of the aforementioned embodiment will be omitted.

First, as shown in FIG. 4A, the P-type polycrystalline silicon wafer 110a is prepared. Then, as shown in FIG. 4B, the surface of P-type polycrystalline silicon wafer 110a becomes uneven by patterning. Next, as shown in FIG. 4C, the plasma is generated by supplying the N-type dopant to the P-type polycrystalline silicon wafer 110a, whereby the N-type polycrystalline silicon layer 120 is formed on the upper surface of P-type polycrystalline silicon wafer 110a.

This procedure corresponds to the plasma ion-doping procedure using the N-type dopant. In more detail, while the P-type polycrystalline silicon wafer 110a is placed in a plasma-generating apparatus such that the upper surface of P-type polycrystalline silicon wafer 110a faces upward, the plasma is generated in the plasma-generation apparatus by supplying the N-type dopant gas such as POCl₃ or PH₃ to the inside of plasma-generating apparatus. Thus, phosphorous (P) ions included in the generated plasma are accelerated by RF electric field so that the upper surface of P-type polycrystalline silicon wafer 110a is doped with the accelerated ions.

After performing the plasma ion-doping procedure, an annealing procedure is performed to heat the P-type polycrystalline silicon wafer 110a to an appropriate temperature, preferably. If not performing the annealing procedure, the doped ions simply serve as impurities. However, if performing the annealing procedure, the doped ions are activated through the combination with silicon Si.

In comparison to the case of using the high-temperature diffusion method, the case of using the plasma ion-doping method has the following advantages.

As compared with the high-temperature diffusion method, the plasma ion-doping method can obtain the more precise doping with high realization through the precise control for doping density and depth by adjusting the gas flow or RF power. Also, the process time is decreased.

Since the plasma ion-doping method is performed at the relatively lower temperature than the high-temperature diffusion method, it is possible to prevent the generation of byproducts (for example, PSG or BSG, which is generated when performing the high-temperature diffusion method). Accordingly, the plasma ion-doping method does not require the additional procedure for removing the byproducts, whereby productivity improves.

Since the ion doping proceeds at a vertical direction, the N-type polycrystalline silicon layer 120 is formed only on the upper surface of P-type polycrystalline silicon wafer 110a. That is, there is no requirement for performing the additional procedure of removing the N-type polycrystalline silicon layer from the lateral and lower surfaces of P-type polycrystalline silicon wafer 110a, whereby productivity improves.

As shown in FIG. 4D, the thin film semiconductor layer 200 with PIN structure is formed on the upper surface of N-type polycrystalline silicon layer 120. The thin film semiconductor layer 200 with PIN structure is formed by sequentially depositing the P-type amorphous silicon layer 210, the I-type amorphous silicon layer 220, and the N-type amorphous silicon layer 230 through the plasma CVD method. Then, as shown in FIG. 4E, the transparent conductive layer 300 is formed on the upper surface of N-type amorphous silicon layer 230. Next, as shown in FIG. 4F, the first electrode layer 400 is formed on the upper surface of transparent conductive layer 300, and the second electrode layer 500 is formed on the lower surface of P-type polycrystalline silicon wafer 110a.

Thereafter, as shown in FIG. 4G, according as the lower surface of P-type polycrystalline silicon wafer 110a is doped with the P-type dopant, the P⁺-type polycrystalline silicon layer 130 is formed on the lower surface of P-type polycrystalline silicon layer 110. This procedure is comprised of doping the lower side of the P-type polycrystalline silicon wafer 110a with aluminum Al by applying the heat treatment to the second electrode layer 500, if the second electrode layer 500 is formed of the trivalent metal such as aluminum Al. However, if the second electrode layer 500 is not formed of the trivalent metal, the P⁺-type polycrystalline silicon layer 130 is formed through the plasma ion-doping method using the dopant gas such as B₂H₆. Preferably, this procedure is performed before forming the second electrode layer 500.

The aforementioned explanation is related with the method of manufacturing the solar cell of FIG. 1. However, the aforementioned explanation also includes the method for manufacturing the solar cell of FIG. 2.

Hereinafter, the method for manufacturing the solar cell of FIG. 2 by forming the semiconductor wafer with PN structure through the use of plasma ion-doping method will be explained in brief.

First, the N-type polycrystalline silicon wafer is prepared. Then, the upper surface of N-type polycrystalline silicon wafer becomes uneven. After that, the plasma is generated by supplying the P-type dopant gas including boron (B), for example, B₂H₆ to the N-type polycrystalline silicon wafer, whereby the P-type polycrystalline silicon layer is formed on the upper surface of N-type polycrystalline silicon wafer.

Thereafter, the thin film semiconductor layer with PIN structure is formed on the upper surface of P-type polycrystalline silicon layer. The thin film semiconductor layer with PIN structure is formed by sequentially depositing the N-type amorphous silicon layer, the I-type amorphous silicon layer, and the P-type amorphous silicon layer through the plasma CVD method. Next, the transparent conductive layer is formed on the upper surface of P-type amorphous silicon layer. Then, the first electrode layer is formed on the upper surface of transparent conductive layer, and the second electrode layer is formed on the lower surface of N-type polycrystalline silicon wafer.

In the meantime, the N⁺-type polycrystalline silicon layer may be formed in the lower side of the N-type polycrystalline silicon wafer. The N⁺-type polycrystalline silicon layer may be formed by the plasma ion-doping method using the N-type dopant gas such as POCl₃ or PH₃, which is preferably performed before forming the second electrode layer.

1. A solar cell comprising:
a first cell comprised of a semiconductor wafer with a PN structure;
a second cell comprised of a thin film semiconductor layer with a PIN structure, formed on one surface of the first cell;
a first electrode layer formed on one surface of the second cell; and
a second electrode layer formed on the other surface of the first cell,
wherein the first cell is comprised of a P-type polycrystalline silicon layer, an N-type polycrystalline silicon layer on one surface of the P-type polycrystalline silicon layer, and a P⁺-type polycrystalline silicon layer on the other surface of the P-type polycrystalline silicon layer.

2. The solar cell according to claim 1, further comprising a transparent conductive layer having an uneven surface, positioned between the second cell and the first electrode layer.

3. (canceled)

4. (canceled)

5. The solar cell according to claim 1, wherein the second cell is comprised of a P-type amorphous silicon layer, an I-type amorphous silicon layer, and an N-type amorphous silicon layer in sequence.

6. A solar cell comprising:
a first cell comprised of a semiconductor wafer with a PN structure;
a second cell comprised of a thin film semiconductor layer with a PIN structure, formed on one surface of the first cell;
a first electrode layer formed on one surface of the second cell; and
a second electrode layer formed on the other surface of the first cell,
wherein the first cell is comprised of an N-type polycrystalline silicon layer, a P-type polycrystalline silicon layer on one surface of the N-type polycrystalline silicon layer, and an N⁺-type polycrystalline silicon layer on the other surface of the N-type polycrystalline silicon layer.

7. (canceled)

8. The solar cell according to claim 6, wherein the second cell is comprised of an N-type amorphous silicon layer, an I-type amorphous silicon layer, and a P-type amorphous silicon layer in sequence.

9. A method for manufacturing a solar cell comprising:
forming a first cell comprised of a semiconductor wafer with a PN structure;
forming a second cell comprised of a thin film semiconductor layer with an PIN structure on one surface of the first cell; and
forming a first electrode layer on one surface of the second cell, and a second electrode layer on the other surface of the first cell,
wherein forming the first cell comprises:
preparing a P-type polycrystalline silicon wafer;
forming an N-type polycrystalline silicon layer on one surface of the P-type polycrystalline silicon wafer by doping the P-type polycrystalline silicon wafer with an N-type dopant; and
forming a P⁺-type polycrystalline silicon layer on the other surface of the P-type polycrystalline silicon wafer.

10. The method according to claim 9, further comprising forming a transparent conductive layer having an uneven surface between the second cell and the first electrode layer.

11. (canceled)

12. The method according to claim 9, wherein preparing the P-type polycrystalline silicon wafer comprises forming one uneven surface in the P-type polycrystalline silicon wafer so as to make one uneven surface in the N-type polycrystalline silicon layer.

13. (canceled)

14. The method according to claim 9, wherein forming the second cell comprises depositing a P-type amorphous silicon layer, an I-type amorphous silicon layer, and an N-type amorphous silicon layer in sequence.

15. A method for manufacturing a solar cell comprising:
forming a first cell comprised of a semiconductor wafer with a PN structure;
forming a second cell comprised of a thin film semiconductor layer with an PIN structure on one surface of the first cell; and
forming a first electrode layer on one surface of the second cell, and a second electrode layer on the other surface of the first cell,
wherein forming the first cell comprises:
forming an N-type polycrystalline silicon wafer;
forming a P-type polycrystalline silicon layer on one surface of the N-type polycrystalline silicon wafer by doping the N-type polycrystalline silicon wafer with a P-type dopant; and
forming an N⁺-type polycrystalline silicon layer on the other surface of the N-type polycrystalline silicon wafer.

16. The method according to claim 15, wherein preparing the N-type polycrystalline silicon wafer comprises forming one uneven surface in the N-type polycrystalline silicon wafer so as to make one uneven surface in the P-type polycrystalline silicon layer.

17. (canceled)

18. The method according to claim 15, wherein forming the second cell comprises depositing an N-type amorphous silicon layer, an I-type amorphous silicon layer, and a P-type amorphous silicon layer in sequence.

19. A solar cell comprising:
a first cell comprised of a semiconductor wafer;
a second cell comprised of a thin film semiconductor layer, formed on one surface of the first cell;
a first electrode layer formed on one surface of the second cell; and
a second electrode layer formed on the other surface of the first cell,
wherein a light-wavelength range absorbed in the first cell is different from a light-wavelength range absorbed in the second cell,
wherein the first cell is comprised of a polycrystalline silicon layer with a PN structure, and the second cell is comprised of an amorphous silicon layer with a PIN structure.

20. (canceled)

21. The solar cell according to claim 6, further comprising a transparent conductive layer having an uneven surface, positioned between the second cell and the first electrode layer.

22. The method according to claim 15, further comprising forming a transparent conductive layer having an uneven surface between the second cell and the first electrode layer.
